(19) United States
(12) Patent Application Publication
(10) Pub. No.: US 2013/0157445 A1
(43) Pub. Date: Jun. 20, 2013

(54) POLYCRYSTALLINE ALUMINUM NITRIDE BASE MATERIAL FOR CRYSTAL GROWTH OF GaN-BASE SEMICONDUCTOR AND METHOD FOR MANUFACTURING GaN-BASE SEMICONDUCTOR USING THE SAME

(71) Applicants: Kimiya Miyashita, Fujisawa-Shi (JP); Michiyasu Komatsu, Yokohama-Shi (JP); Katsuyuki Aoki, Yokohama-Shi (JP); Kai Funaki, Yokohama-Shi (JP)

(72) Inventors: Kimiya Miyashita, Fujisawa-Shi (JP); Michiyasu Komatsu, Yokohama-Shi (JP); Katsuyuki Aoki, Yokohama-Shi (JP); Kai Funaki, Yokohama-Shi (JP)

(21) Appl. No.: 13/806,320

(22) PCT Filed: Aug. 3, 2011
(86) PCT No.: PCT/JP2011/067749

§ 371 Date: Feb. 26, 2013

(30) Foreign Application Priority Data
Aug. 10, 2010 (JP) 2010-179833

(51) Int. Cl. H01L 21/02; C04B 35/581

(52) U.S. Cl. CPC H01L 21/02389; C04B 35/581
USPC 438/478; 428/64.1; 428/220; 501/98.4; 501/98.6

(57) ABSTRACT

There is provided a polycrystalline aluminum nitride base material having a linear expansion coefficient similar to GaN. The polycrystalline aluminum nitride base material as a substrate material for crystal growth of GaN-base semiconductors has a mean linear expansion coefficient of 4.9×10⁻⁶/K to 6.1×10⁻⁶/K between 20° C. and 600° C. and 5.5×10⁻⁶/K to 6.6×10⁻⁶/K between 20° C. and 1100° C.

### TECHNICAL FIELD

The present invention relates to a polycrystalline aluminum nitride base material for the growth of a GaN-base semiconductor crystal and a method for manufacturing a GaN-base semiconductor using the same.

### BACKGROUND ART

The development of new light sources, for example, LEDs (light emitting diodes), photosemiconductor devices such as semiconductor lasers, and power devices using wide band gap semiconductors has been promoted from the viewpoints of environmental problems and energy saving.

Regarding semiconductors for use in these devices, gallium nitride (GaN) base semiconductors such as GaN, InGaN, AlGaN, and InAlGaN have drawn attention and have been used as layers constituting the devices. For example, LED elements have a structure including a stack of a plurality of thin GaN-base layers. For example, Japanese Patent Laid-Open No. 111766/2004 (patent document 1) uses a multilayer structure of a GaN layer and a GaAlN layer. The yield of semiconductor is governed by the efficiency of the formation of and the evenness of thickness of the thin semiconductor layers.

Epitaxial growth is generally used for the manufacture of gallium nitride (GaN) base semiconductor devices. Up to now, sapphire or SiC substrates have been used as epitaxial substrates. These substrates, however, suffer from problems such as high cost (sapphire and SiC) and warpage due to a difference in linear expansion coefficient between gallium nitride and substrate materials.

The linear expansion coefficient of GaN (a-plane), the linear expansion coefficient of sapphire, and the linear expansion coefficient of SiC are 5.59×10⁻⁶/K, approximately 7×10⁻⁶/K to 8×10⁻⁶/K, and approximately 6.6×10⁻⁶/K, respectively, and the difference in linear expansion coefficient between the GaN (a-plane), the sapphire, and SiC is approximately not less than 1×10⁻⁶/K. For example, in paragraph [0051] of patent document 1, a GaN layer is epitaxially grown on a sapphire substrate at an elevated temperature of about 1100° C. Exposure to such elevated temperature worsens the problem of warpage attributable to the difference in linear expansion coefficient. Further, in recent years, the growth of the GaN layer using sapphire substrates having a larger size has been desired from the viewpoint of increasing the number of acceptable semiconductor chips obtained per semiconductor substrate.

### PRIOR ART DOCUMENT

### Patent Document

Patent document 1: Japanese Patent Laid-Open No. 111766/2004

### DISCLOSURE OF THE INVENTION

### Problems to be Solved by the Invention

Due to the difference in linear expansion coefficient between the GaN (gallium nitride) base crystal and the epitaxial substrate, warpage occurs after the epitaxial growth, and, at the worst, disadvantageously, cracking occurs. To overcome this problem, the development of a crystal growth method using a GaN epitaxial substrate that is free from warpage has been desired. However, any satisfactory method has not been developed yet. Further, the cost of the epitaxial substrate should be reduced for manufacturing cost reduction purposes. Accordingly, an object of the present invention is to obtain an inexpensive material for the production of a gallium nitride-base crystal having no significant warpage.

### Means for Solving the Problems

According to the present invention, there is provided a polycrystalline aluminum nitride base material for use as a substrate material for grain growth of GaN-base semiconductors, the polycrystalline aluminum nitride base material having a mean linear expansion coefficient of 4.9×10⁻⁸/K to 6.1×10⁻⁶/K between 20° C. and 600° C. and 5.5×10⁻⁶/K to 6.6×10⁻⁶/K between 20° C. and 1,100° C.

In an embodiment of the present invention, preferably, the polycrystalline aluminum nitride base material comprises an aluminum nitride crystal and a grain boundary phase, and the content of the aluminum nitride crystal is 56.2% to 93.9% in terms of volume fraction.

In an embodiment of the present invention, preferably, the grain boundary phase comprises a composite oxide composed of at least one material selected from the group consisting of Ca (calcium), Y (yttrium), La (lanthanum), Ce (cerium), Nd (neodymium), Pr (praseodymium), Eu (europium), Gd (gadolinium), Dy (dysprosium), Ho (holmium), Er (erbium), Yb (ytterbium), and Lu (lutetium) and aluminum.

In an embodiment of the present invention, preferably, the grain boundary phase contains titanium nitride (TiN).

In an embodiment of the present invention, preferably, crystal grains of the aluminum nitride have a mean diameter of not more than 7 μm.

In an embodiment of the present invention, preferably, the polycrystalline aluminum nitride base material has a thermal conductivity of not less than 46 W/m·K.

In an embodiment of the present invention, preferably, the polycrystalline aluminum nitride base material has a diameter of not less than 50 mm.

In an embodiment of the present invention, preferably, the polycrystalline aluminum nitride base material has a surface roughness (Ra) of not more than 0.2 μm and a thickness of not more than 3 mm.

According to another aspect of the present invention, there is provided a method for manufacturing a GaN-base semiconductor, the process comprising: growing a GaN-base semiconductor crystal using the above polycrystalline aluminum nitride base material.

In an embodiment of the present invention, preferably, the GaN-base semiconductor crystal is grown through a buffer layer.

In an embodiment of the present invention, preferably, the GaN-base semiconductor is at least one semiconductor selected from the group consisting of GaN, InGaN, AlGaN, and InAlGaN.

### Effect of the Invention

The present invention can provide a polycrystalline aluminum nitride substrate having a linear thermal expansion coefficient between room temperature and 1100° C. that is close to GaN and can also realize the production of a GaN-base semiconductor using the polycrystalline aluminum nitride substrate at a good yield.

### BRIEF DESCRIPTION OF THE INVENTION

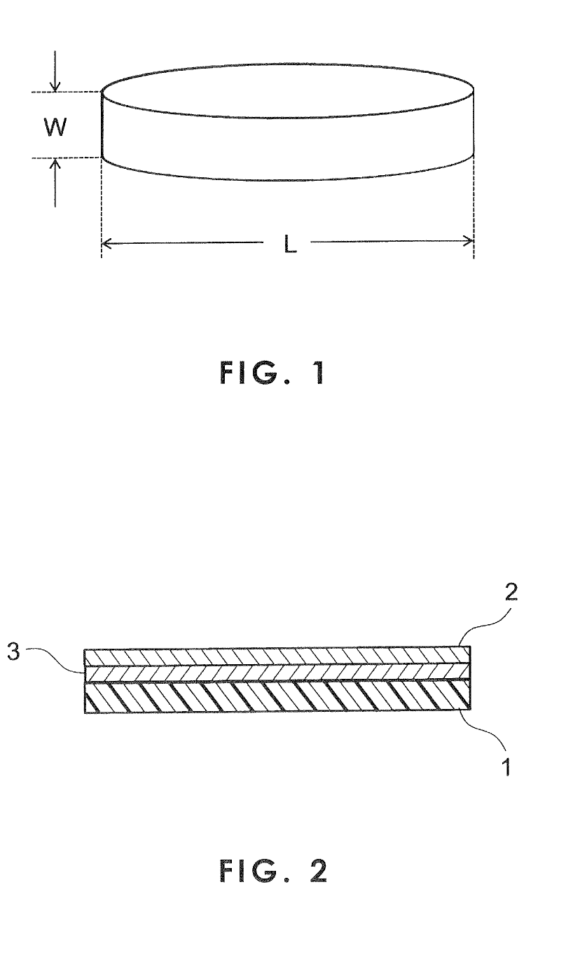

FIG. 1 is a diagram showing one embodiment of a polycrystalline aluminum nitride base material for crystal growth of GaN-base semiconductors according to the present invention.

FIG. 2 is a diagram showing one embodiment of a method for manufacturing a GaN-base semiconductor according to the present invention.

### BEST MODE FOR CARRYING OUT THE INVENTION

The polycrystalline aluminum nitride base material according to the present invention is a polycrystalline aluminum nitride base material for use as a substrate material for crystal growth of GaN-base semiconductors, the polycrystalline aluminum nitride base material having a mean linear expansion coefficient of 4.9×10⁻⁶/K to 6.1×10⁻⁶/K between 20° C. and 600° C. and 5.5×10⁻⁶/K to 6.6×10⁻⁶/K between 20° C. and 1100° C.

The polycrystalline aluminum nitride substrate means a substrate obtained by compacting an aluminum nitride powder by sintering. The present invention is characterized in that the polycrystalline aluminum nitride substrate has a mean linear expansion coefficient of 4.9×10⁻⁶/K to 6.1×10⁻⁶/K between 20° C. and 600° C. and 5.5×10⁻⁶/K to 6.6×10⁻⁶/K between 20° C. and 1100° C.

The linear expansion coefficient means a value of a change in length when the material underwent a temperature change. The linear expansion coefficient is measured by a method according to JIS (Japanese Industrial Standards) R 1618 and is expressed in “/K (kelvin).” In the present invention, for example, the mean linear expansion coefficient between 20° C. and 600° C. is a value obtained by dividing an increase in length (expansion rate) at 600° C., a temperature raised from 20° C. (as a reference), by a temperature difference, 580° C. On the other hand, the mean linear expansion coefficient between 20° C. and 1100° C. is a value obtained by dividing an increase in length (expansion rate) at 1100° C., a temperature raised from 20° C. (as a reference), by a temperature difference, 1080° C.

What is to be generally considered in epitaxial growth is mainly a linear expansion coefficient of GaN (a-plane). At a temperature around room temperature, the linear expansion coefficient of GaN (a-plane) is 5.59×10⁻⁶/K, whereas the linear expansion coefficient of sapphire and the linear expansion coefficient of SiC are approximately 7×10⁻⁶/K to 8×10⁻⁶/K and approximately 6.6×10⁻⁶/K, respectively, that is, the difference in linear expansion coefficient between GaN (a-plane) and sapphire and SiC is approximately 1.0×10⁻⁶/K. Sapphire and SiC are single crystals, and the linear expansion coefficient as a material cannot be regulated. In order to eliminate the problem of the linear expansion coefficient difference, the size of the GaN-base semiconductor should be reduced. This, however, results in a lowering in weight productivity of semiconductor elements (for example, LEDs and semiconductor lasers) that is a factor of cost increase.

By contrast, the polycrystalline aluminum nitride substrate according to the present invention has a mean linear expansion coefficient of 4.9×10⁻⁶/K to 6.1×10⁻⁶/K between 20° C. and 600° C. and 5.5×10⁻⁶/K to 6.6×10⁻⁶/K between 20° C. and 1100° C. and thus can reduce the problem of warpage even when GaN-base semiconductors having a larger diameter are manufactured, contributing to improved weight productivity of semiconductor elements.

Preferably, the polycrystalline aluminum nitride base material includes an aluminum nitride crystal and a grain boundary phase, and the content of the aluminum nitride crystal is 56.2% to 93.9% in terms of volume fraction. The polycrystal is one obtained by compacting an aluminum nitride powder (AlN powder) by sintering. The use of the sintering aid is preferred for sinterability improvement purposes. The expression “the content of the aluminum nitride crystal is 56.2% to 93.9% in terms of volume fraction” means that the balance consists of a grain boundary phase. When the content of the aluminum nitride crystal is less than 56.2% or more than 93.9%, the contemplated linear expansion coefficient is less likely to be obtained. The porosity is preferably not more than 1% by volume, more preferably not more than 0.5% by volume. In order to grow the GaN layer on the polycrystalline aluminum nitride substrate, the surface of the substrate should be free from pore-derived irregularities, that is, flat. To meet this requirement, the substrate preferably has a surface roughness Ra of not more than 0.2 μm and is preferably planished to a provide a surface roughness of not more than 0.05 μm.

Preferably, the grain boundary phase contains a composite oxide composed of at least one material selected from the group consisting of Ca (calcium), Y (yttrium), La (lanthanum), Ce (cerium), Nd (neodymium), Pr (praseodymium), Eu (europium), Gd (gadolinium), Dy (dysprosium), Ho (holmium), Er (erbium), Yb (ytterbium), and Lu (lutetium) and aluminum. The grain boundary phase is a phase that is formed as a result of a conversion of the sintering aid during the sintering. The presence of the grain boundary phase contributes to improved sinterability and facilitates the regulation of the linear thermal expansion coefficient. These components of the grain boundary phase have a larger linear expansion coefficient than the aluminum nitride crystal and are effective in regulating the linear expansion coefficient of the aluminum nitride substrate. Whether the composite oxide is formed can be determined by XRD,

At least one material selected from the group consisting of Ca, Y, La, Ce, Nd, Pr, Eu, Gd, Dy, Ho, Er, Yb, and Lu has the effect of enhancing the sinterability and is preferably added as an oxide. The use of these rare earth elements can realize pressureless sintering. Impurity oxygen in the aluminum nitride powder may be utilized as the oxide of aluminum as the second sintering aid, or alternatively, aluminum oxide may be added as the sintering aid because the presence of aluminum oxide facilitates the formation of the first sintering aid and the composite oxide. The composite oxide can easily regulate the linear expansion coefficient and is stable even at an elevated temperature around 1100° C. Preferably, at least one material selected from the group consisting of Ca, Y, La, Ce, Nd, Pr, Eu, Gd, Dy, Ho, Er, Yb, and Lu is contained as the first sintering aid in an amount of 4 to 30% by weight in terms of oxide. Preferably, aluminum is contained as the second sintering aid in an amount of 1 to 23% by weight in terms of oxide.

The addition of 5 to 25% by weight of TiN (titanium nitride) as the third sintering aid is also effective in regulating the linear expansion coefficient. The rare earth elements as the first sintering aid are expensive. Replacement of part of the rare earth elements with TiN can reduce cost while regulating the linear expansion coefficient. Further, the combined use of TiN and the first sintering aid can realize the manufacture by pressureless sintering.

It is also possible to regulate the linear expansion coefficient with only TiN without use of the first sintering aid as the component of the grain boundary phase. In this case, the sinterability is poor because the first sintering aid is not used. Accordingly, the adoption of pressure sintering by hot press or the like is preferred.

The mean grain diameter of aluminum nitride crystal grains is preferably not more than 7 μm. The presence of a grain boundary phase having a larger linear expansion coefficient than the aluminum nitride crystal grains at the grain boundary between the aluminum nitride crystal grains is effective in regulating the linear thermal expansion coefficient. When the aluminum nitride crystal grains are excessively large, the proportion of presence between the aluminum nitride crystal grains and the grain boundary phase is heterogeneous. Accordingly, there is a possibility that a partial variation in linear expansion coefficient occurs. When the aluminum nitride crystal grains have a relatively small diameter of not more than 7 μm, the partial variation can be reduced. The lower limit of the mean grain diameter is not particularly limited but is preferably not less than 1 μm. When the mean grain diameter is less than 1 μm, a starting material powder having a small particle diameter should be used, leading to an increase in starting material cost. When the mean grain diameter is not more than 7 μm, even when aluminum nitride crystal grains come off by polishing, large craters (traces after removal of grains) are not formed and, consequently, a flat face can easily be obtained. Obtaining a flat face is also important for crystal growth of a GaN base.

Preferably, the polycrystalline aluminum nitride substrate has a thermal conductivity of not less than 46 W/m·K. When the thermal conductivity is high, heat radiation during crystal growth of GaN-base semiconductors is enhanced, contributing to the suppression of expansion-derived warpage. For example, the thermal conductivity of the sapphire substrate is approximately 46 W/m·K. When the main phase is formed of aluminum nitride crystal grains having a high thermal conductivity, a higher thermal conductivity can be realized. The upper limit of the thermal conductivity is not particularly limited. However, when the content of the sintering aid is high, the thermal conductivity is not more than 170 W/m·K.

The polycrystalline aluminum nitride substrate described above can allow the warpage to be suppressed under high temperatures, and, thus, a substrate having a diameter L of not less than 100 mm can be realized. The upper limit of the diameter is not particularly limited. When easiness on the manufacture is taken into consideration, the diameter L is preferably not more than 300 mm. In FIG. 1, the polycrystalline aluminum nitride substrate has a disk shape. However, the crystal growth face may be square or rectangular.

The thickness of the substrate is preferably not more than 3 mm. The substrate according to the present invention can allow the coefficient of thermal expansion to be regulated while bringing the thickness to be small, that is, to be not more than 3 mm.

Further, the thickness W of the substrate is preferably 0.3 mm to 1.5 mm, more preferably 0.5 mm to 1.0 mm. When the thickness is more than 1.5 mm, the heat radiation is deteriorated. On the other hand, when the thickness is less than 0.3 mm, the strength of the substrate is unsatisfactory and the handleability is lowered.

The polycrystalline aluminum nitride substrate, the thickness of which is in the above-defined range, is effective as a substrate material for the crystal growth of GaN-base semiconductors. The method for manufacturing a GaN-base semiconductor using the above polycrystalline aluminum nitride substrate will be described. FIG. 2 is a schematic cross-sectional view showing one embodiment of a manufacturing process of a GaN-base semiconductor. In the drawing, numeral 1 designates a polycrystalline aluminum nitride base material, numeral 2 a GaN-base semiconductor layer, and numeral 3 a buffer layer. At the outset, a buffer layer is formed on the polycrystalline aluminum nitride substrate 1. The buffer layer is preferably formed of the same material as the GaN-base semiconductor layer. The crystal of the GaN-base semiconductor is grown on the buffer layer.

The GaN-base semiconductor is preferably at least one material selected from the group consisting of GaN, InGaN, AlGaN, and InAlGaN. All the materials are based on GaN. The linear expansion coefficient of GaN (a-plane) is around 5.59×10⁻⁶/K. In the step of growing the GaN-base semiconductor crystal, a polycrystalline aluminum nitride substrate 1 is placed on a susceptor (not shown), and a GaN buffer layer is formed at 500 to 600° C. by a metal organic vapor phase epitaxial growth method (MOCVD method) while allowing a TMG gas (trimethyl gallium gas) and an ammonium gas to flow. The thickness of the GaN layer is increased (by crystal growth) at 1000° C. to 1100° C. Since the MOCVD method is carried out under an elevated temperature of 500° C. to 1100° C., the regulation of the linear expansion coefficient in this temperature range is effective. In particular, the expansion or shrinkage of the substrate in the step of cooling from an elevated temperature of 1100° C. to 600° C. affects warpage. In the polycrystalline aluminum nitride substrate according to the present invention, the problem of the warpage can be significantly suppressed because the linear expansion coefficient is brought to a value close to the GaN-base semiconductor. Accordingly, even when the diameter of the polycrystalline aluminum nitride substrate is increased to not less than 50 mm, the warpage can be suppressed. As a result, the GaN-base semiconductor can be grown in a large area, and, thus, a number of light emitting elements can be obtained per polycrystalline aluminum nitride substrate, contributing to improved weight productivity. It is needless to say that, for example, the formation of various layers such as a GaN-base semiconductor layer and an insulating layer and etching are carried out in manufacturing light emitting elements such as LEDs and semiconductor lasers. Further, in manufacturing light emitting elements, the polycrystalline aluminum nitride substrate may be removed if unnecessary. When the polycrystalline aluminum nitride substrate includes a grain boundary phase, the polycrystalline aluminum nitride substrate can easily be removed with an alkaline solution or the like, or alternatively can be scraped off. When the efficiency of the step of removing the substrate for weight production is taken into consideration, the thickness of the polycrystalline aluminum nitride substrate is preferably not more than 3 mm.

The method for manufacturing a polycrystalline aluminum nitride substrate according to the present invention will be described. The polycrystalline aluminum nitride substrate may be manufactured by any method without particular limitation. An example of a method that can manufacture the polycrystalline aluminum nitride substrate at a high yield will be described.

At the outset, an aluminum nitride powder is provided as the starting material powder. Preferably, the aluminum nitride powder has a mean particle diameter of 0.6 μm to 2 μm. When the mean particle diameter is less than 0.6 μm, the particle diameter is so small that there is a possibility that the cost of the aluminum nitride powder is increased. On the other hand, when the mean particle diameter is more than 2 μm, there is a high possibility that the mean grain diameter of the aluminum nitride crystal after sintering exceeds 7 μm. More preferably, an aluminum nitride powder having a mean particle diameter of 1.0 μm to 1.5 μm is used. Preferably, the content of oxygen in the aluminum nitride powder is 0.6 to 2% by weight.

Next, a first sintering aid (an oxide of at least one element selected from the group consisting of Ca, Y, La, Ce, Nd, Pr, Eu, Gd, Dy, Ho, Er, Yb, and Lu), a second sintering aid (an oxide of aluminum), and a third sintering aid (TiN) are prepared as sintering aids in respective necessary amounts and are mixed with the aluminum nitride powder. The mean particle diameter of the sintering aid is preferably similar to that of the aluminum nitride powder and is 0.6 μm to 2 μm. Regarding the addition amount of the sintering aid, the sintering aid is mixed so that the content of the aluminum nitride crystal is 56.2% to 93.9% in terms of volume fraction. When the mean particle diameter of the sintering aid powder is similar to that of the aluminum nitride powder, the volume fraction can easily be regulated.

Next, the aluminum nitride powder, the sintering aid powder, a binder, a solvent, a dispersant and the like are mixed to prepare a starting material slurry.

Subsequently, a molded product is prepared using the starting material slurry thus prepared. Examples of molding methods include sheet forming using doctor blading and press molding in which granules prepared from the slurry is molded in a mold. Large molded products having a diameter of not less than 50 mm and even not less than 100 mm can easily prepared by doctor blading. The molded product is in a sheet form, if necessary, the molded product may be fabricated into a disk form.

Next, the step of sintering the molded product is carried out. The sintering temperature is preferably 1600° C. to 1900° C. When the first sintering aid is used as the sintering aid, sintering can be carried out by pressureless sintering. When the first sintering aid is not used, preferably, pressure sintering is used with a hot press or the like. Preferably, the sintering is carried out in an inert atmosphere.

In the sintered compact thus obtained, the GaN-base semiconductor formed surface is planished. The surface is polished with a diamond wheel to a surface roughness Ra of not more than 0.2 μm, preferably not more than 0.05 μm. Further, if necessary, the sintered compact may be worked to adjust the shape of the side surface and back surface.

### EXAMPLES

The present invention is further illustrated by Examples that are not intended as a limitation of the invention.

### Example 1

An aluminum nitride powder (mean particle diameter 1 μm, oxygen content 1.0% by weight) and a yttria (Y₂O₃) powder (mean particle diameter 1 μm), and an alumina (Al₂O₃) powder (mean particle diameter 1 μm) were mixed together at a mixing ratio specified in Table 1 to prepare a starting material powder. Regarding the mixing amounts in the table, yttria that is a first sintering aid, alumina that is a second sintering aid, and the aluminum nitride powder were mixed together to give a 100 parts by weight of the starting material powder.

After the mixing, the starting material powder was added to a solvent such as toluene or ethanol, and a dispersant was added thereto. Thereafter, an organic binder and a plasticizer were added followed by further mixing. The mixture was formed into a 1.2 mm-thick green sheet by doctor blading. The green sheet was cut into a size of 170 mm in length×170 mm in width, was then degreased, and was sintered under conditions of 1700° C.×5 hr to prepare a polycrystalline aluminum nitride substrate of sample 1. The same procedure was repeated to prepare polycrystalline aluminum nitride substrates of samples 2 to 8.

For each sample, the coefficient of linear thermal expansion was measured according to JIS (Japanese Industrial Standards) R 1618. The linear expansion coefficient was measured from 20° C. to 1300° C. at intervals of 0.1° C. to 0.3° C. Values at intervals of 100° C. were shown as representative values. The grain boundary phase was then analyzed by XRD (X-ray diffractometry) to determine phases constituting the grain boundary phase. The thermal conductivity was measured by a laser flash method. Further, the mean diameter of crystal grains of aluminum nitride was measured. The mean diameter of crystal grains of aluminum nitride was measured by taking an enlarged photograph (100 μm×100 μm) of a cross section of any portion of a sample and determining diameters of the crystal grains by a line intercept method. The results are shown in Table 1.

TABLE 1

| | Sample 1 | Sample 2 | Sample 3 | Sample 4 | Sample 5 | Sample 6 | Sample 7 | Sample 8 |
|---|---|---|---|---|---|---|---|---|
| Mixing amount of | 0.9 | 4.7 | 10.0 | 15.0 | 20.0 | 25.0 | 30.0 | 35.0 |
| Y₂O₃ (pts. wt) | | | | | | | | |
| Mixing amount of | 0.0 | 1.9 | 6.0 | 10.0 | 13.8 | 18.0 | 21.0 | 26.0 |
| Al₂O₃ (pts. wt) | | | | | | | | |
| Volume fraction of | 98.1 | 93.9 | 86.7 | 79.5 | 71.9 | 63.7 | 56.2 | 46.2 |
| AlN phase in | | | | | | | | |
| sintered compact | | | | | | | | |
| Mean grain | 10.0 | 7.0 | 4.9 | 3.5 | 2.3 | 2.4 | 2.4 | 2.3 |
| diameter (μm) | | | | | | | | |
| Constituent phase | Mainly | Mainly | Mainly | Mainly | Mainly | Mainly | Mainly | Mainly |
| other than AlN | YAM | YAP | YAP | YAG | YAG | YAG | YAG | YAG |
| Thermal | 230 | 165 | 130 | 108 | 89 | 74 | 54 | 42 |
| conductivity | | | | | | | | |
| (W/mK) | | | | | | | | |
| Temp. (° C.) | Mean linear expansion coefficient (×10⁻⁶/° C.) [20° C.-T° C.] | | | | | | | |
| 20-100 | 2.5 | 3.2 | 3.6 | 3.8 | 4.0 | 4.3 | 4.5 | 4.8 |
| 20-200 | 3.4 | 3.9 | 4.2 | 4.4 | 4.6 | 4.9 | 5.2 | 5.5 |
| 20-300 | 3.8 | 4.3 | 4.5 | 4.7 | 4.9 | 5.2 | 5.5 | 5.7 |
| 20-400 | 4.2 | 4.5 | 4.7 | 5.0 | 5.2 | 5.4 | 5.7 | 6.0 |
| 20-500 | 4.5 | 4.8 | 5.0 | 5.2 | 5.4 | 5.7 | 5.9 | 6.2 |
| 20-600 | 4.7 | 4.9 | 5.1 | 5.4 | 5.6 | 5.8 | 6.1 | 6.3 |
| 20-700 | 4.9 | 5.1 | 5.3 | 5.5 | 5.8 | 6.0 | 6.2 | 6.5 |
| 20-800 | 5.0 | 5.2 | 5.5 | 5.7 | 5.9 | 6.1 | 6.4 | 6.6 |
| 20-900 | 5.1 | 5.3 | 5.5 | 5.8 | 6.0 | 6.2 | 6.4 | 6.6 |
| 20-1000 | 5.3 | 5.5 | 5.7 | 5.9 | 6.1 | 6.3 | 6.5 | 6.7 |
| 20-1100 | 5.3 | 5.5 | 5.8 | 6.0 | 6.2 | 6.4 | 6.6 | 6.8 |
| 20-1200 | 5.4 | 5.6 | 5.8 | 6.0 | 6.3 | 6.5 | 6.7 | 6.9 |
| 20-1300 | 5.4 | 5.6 | 5.9 | 6.1 | 6.3 | 6.5 | 6.8 | 7.0 |

In Table 1, samples 2 to 7 are Examples, and samples 1 and 8 are Comparative Examples. For each sample, a YAG phase (Y₃Al₅O₁₂) or a YAP phase (YAlO₃) that is a composite oxide is detected in the grain boundary phase. The composite oxide was identified by XRD.

### Example 2

An experiment was carried out in the same manner as in Example 1, except that Gd₂O₃ (samples 9 to 14) was used as the first sintering aid and alumina was used as the second sintering aid. The aluminum nitride powder (impurity oxygen content 1.2% by weight), the first sintering aid, and the second sintering aid used each had a mean particle diameter of 1.2 μm. The sintering was carried out at a temperature in the range of 1700° C. to 1800° C. and, for all the sheets, the sintering was carried out in a nitrogen atmosphere. For the samples thus obtained, measurements were carried out in the same manner as in Example 1. The results are shown in Table 2.

TABLE 2

| | Sample 9 | Sample 10 | Sample 11 | Sample 12 | Sample 13 | Sample 14 |
|---|---|---|---|---|---|---|
| Mixing amount of | 0.9 | 4.7 | 10.0 | 20.2 | 30.0 | 35.0 |
| Gd₂O₃ (pts. wt) | | | | | | |
| Mixing amount of | 0.0 | 1.9 | 6.0 | 8.4 | 21.0 | 26.0 |
| Al₂O₃ (pts. wt) | | | | | | |
| Volume fraction of | 97.6 | 92.1 | 85.6 | 80.0 | 58.5 | 48.6 |
| AlN phase in | | | | | | |
| sintered compact | | | | | | |
| Mean grain diameter | 9.7 | 6.9 | 4.8 | 3.4 | 2.5 | 2.3 |
| (μm) | | | | | | |
| Constituent phase | Mainly | Mainly | Mainly | Mainly | Mainly | Mainly |
| other than AlN | 2Gd₂O₃•Al₂O₃ | Gd₂O₃•Al₂O₃ | Gd₂O₃•Al₂O₃ | 3Gd₂O₃•5Al₂O₃ | 3Gd₂O₃•5Al₂O₃ | 3Gd₂O₃•5Al₂O₃ |
| Thermal conductivity | 210 | 159 | 124 | 101 | 56 | 39 |
| (W/mK) | | | | | | |

| Temp. (° C.) | Mean linear expansion coefficient (×10⁻⁶/° C.) | | | | | |
|---|---|---|---|---|---|---|
| 20-100 | 2.4 | 2.8 | 3.3 | 3.8 | 4.2 | 4.6 |
| 20-200 | 3.3 | 3.7 | 4.0 | 4.4 | 4.8 | 5.2 |
| 20-300 | 3.7 | 4.1 | 4.4 | 4.6 | 5.0 | 5.4 |
| 20-400 | 4.0 | 4.4 | 4.7 | 5.0 | 5.4 | 5.8 |
| 20-500 | 4.4 | 4.8 | 5.0 | 5.2 | 5.6 | 6.0 |
| 20-600 | 4.5 | 4.9 | 4.2 | 5.4 | 5.8 | 6.2 |
| 20-700 | 4.8 | 5.2 | 5.3 | 5.5 | 5.9 | 6.3 |
| 20-800 | 4.8 | 5.2 | 5.4 | 5.7 | 6.0 | 6.3 |
| 20-900 | 5.0 | 5.4 | 5.6 | 5.8 | 6.2 | 6.6 |
| 20-1000 | 5.2 | 5.6 | 5.7 | 5.9 | 6.2 | 6.6 |
| 20-1100 | 5.2 | 5.6 | 5.7 | 5.9 | 6.2 | 6.7 |
| 20-1200 | 5.3 | 5.7 | 5.8 | 6.0 | 6.4 | 6.7 |
| 20-1300 | 5.3 | 5.7 | 5.8 | 6.0 | 6.4 | 6.8 |

In Table 2, samples 10 to 13 are Examples, and samples 9 and 14 are Comparative Examples. For each sample, a Ga₃Al₅O₁₂ or GaAlO₃ that is a composite oxide was detected in the grain boundary phase. The results show that, even when the first sintering aid was changed to Gd₂O₃, the linear expansion coefficient could be regulated.

### Example 3

An experiment was carried out in the same manner as in Example 1, except that Dy₂O₃ (samples 15 to 20) was used as the first sintering aid and alumina was used as the second sintering aid. The aluminum nitride powder (impurity oxygen content 1.2% by weight), the first sintering aid, and the second sintering aid used each had a mean particle diameter of 1.2 μm. The sintering was carried out at a temperature in the range of 1700° C. to 1800° C. and, for all the sheets, the sintering was carried out in a nitrogen atmosphere. For the samples thus obtained, measurements were carried out in the same manner as in Example 1. The results are shown in Table 3.

TABLE 3

| | Sample 15 | Sample 16 | Sample 17 | Sample 18 | Sample 19 | Sample 20 |
|---|---|---|---|---|---|---|
| Mixing amount of | 0.9 | 4.7 | 10.0 | 22.0 | 30.0 | 35.0 |
| Gy₂O₃ (pts. wt) | | | | | | |
| Mixing amount of | 0.0 | 1.9 | 4.6 | 8.9 | 15.0 | 16.0 |
| Al₂O₃ (pts. wt) | | | | | | |
| Volume fraction of | 98.0 | 93.4 | 86.3 | 80.0 | 59.2 | 49.8 |
| AlN phase in | | | | | | |
| sintered compact | | | | | | |
| Mean grain diameter | 9.8 | 7.0 | 4.9 | 3.5 | 2.6 | 2.4 |
| (μm) | | | | | | |
| Constituent phase | Mainly | Mainly | Mainly | Mainly | Mainly | Mainly |
| other than AlN | 2Dy₂O₃•Al₂O₃ | Dy₂O₃•Al₂O₃ | Dy₂O₃•Al₂O₃ | 3Dy₂O₃•5Al₂O₃ | 3Dy₂O₃•5Al₂O₃ | 3Dy₂O₃•5Al₂O₃ |
| Thermal conductivity | 205 | 152 | 117 | 96 | 57 | 40 |
| (W/mK) | | | | | | |
| Temp. (° C.) | Mean linear expansion coefficient (×10⁻⁶/° C.) | | | | | |
| 20-100 | 2.3 | 2.8 | 3.3 | 3.8 | 4.2 | 4.5 |
| 20-200 | 3.3 | 3.7 | 4.1 | 4.4 | 4.8 | 5.3 |
| 20-300 | 3.8 | 4.0 | 4.3 | 4.7 | 5.2 | 5.4 |
| 20-400 | 4.0 | 4.4 | 4.7 | 5.0 | 5.4 | 5.6 |
| 20-500 | 4.3 | 4.8 | 4.9 | 5.1 | 5.5 | 6.0 |
| 20-600 | 4.5 | 4.9 | 4.2 | 5.3 | 5.7 | 6.3 |
| 20-700 | 4.6 | 5.2 | 5.3 | 5.5 | 5.9 | 6.3 |
| 20-800 | 4.8 | 5.2 | 5.4 | 5.7 | 6.1 | 6.3 |
| 20-900 | 5.1 | 5.4 | 5.7 | 5.8 | 6.1 | 6.5 |
| 20-1000 | 5.1 | 5.5 | 5.7 | 5.9 | 6.2 | 6.6 |
| 20-1100 | 5.2 | 5.6 | 5.7 | 6.0 | 6.3 | 6.6 |
| 20-1200 | 5.3 | 5.7 | 5.8 | 6.0 | 6.3 | 6.7 |
| 20-1300 | 5.3 | 5.7 | 5.9 | 6.1 | 6.4 | 6.7 |

In Table 3, samples 16 to 19 are Examples, and samples 15 and 20 are Comparative Examples. For each sample, a Dy₃Al₅O₁₂ or DyAlO₃ that is a composite oxide was detected in the grain boundary phase. The results show that, even when the first sintering aid was changed to Dy₂O₃, the linear expansion coefficient could be regulated. The composite oxide was identified by XRD.

### Example 4

Ho₂O₃ (sample 21), Er₂O₃ (sample 22), or Yb₂O₃ (sample 23) was used as the first sintering aid, and alumina was used as the second sintering aid. These materials were added in such amounts that the volume fraction of the AlN sintered compact was 80%. The aluminum nitride powder (impurity oxygen content 1.2% by weight), the first sintering aid, and the second sintering aid used each had a mean particle diameter of 1.2 μm. The sintering was carried out at a temperature in the range of 1700° C. to 1800° C. and, for all the sheets, the sintering was carried out in a nitrogen atmosphere. For the samples thus obtained, measurements were carried out in the same manner as in Examples 1 to 3. The results are shown in Table 4.

TABLE 4

| | Sample 21 | Sample 22 | Sample 23 |
|---|---|---|---|
| | (Ho₂O₃) | (Er₂O₃) | (Yb₂O₃) |
| Mixing amount of Ln₂O₃ | 22.0 | 20.3 | 21.4 |
| (pts. wt) | | | |
| Mixing amount of Al₂O₃ | 8.8 | 8.0 | 8.2 |
| (pts. wt) | | | |
| Volume fraction of AlN | 80 | | |
| phase in sintered compact | | | |
| Mean grain diameter (μm) | 3.4 | 3.3 | 3.4 |
| Constituent phase other | Composite oxide composed of each | | |
| than AlN | lanthanoid (Ln₂O₃) and aluminum oxide | | |
| Thermal conductivity | 95 | 95 | 89 |
| (W/mK) | | | |
| | Mean linear expansion coefficient | | |
| Temp. (° C.) | (×10⁻⁶/° C.) | | |
| 20-100 | 3.8 | 3.7 | 3.7 |
| 20-200 | 4.4 | 4.4 | 4.4 |
| 20-300 | 4.7 | 4.7 | 4.7 |
| 20-400 | 5.0 | 4.9 | 5.0 |
| 20-500 | 5.2 | 5.2 | 5.2 |
| 20-600 | 5.4 | 5.4 | 5.4 |
| 20-700 | 5.6 | 5.5 | 5.5 |
| 20-800 | 5.7 | 5.6 | 5.6 |
| 20-900 | 5.8 | 5.8 | 5.8 |
| 20-1000 | 5.9 | 5.8 | 5.9 |
| 20-1100 | 6.0 | 5.9 | 6.0 |
| 20-1200 | 6.0 | 6.0 | 6.0 |
| 20-1300 | 6.1 | 6.0 | 6.1 |

The results in Table 4 show that, even when the sintering aid was changed to those other than those used in Examples 1 to 3, the linear expansion coefficient could be regulated.

### Example 5

A polycrystalline aluminum nitride substrate was prepared using yttria as the first sintering aid, alumina as the second sintering aid, and titanium nitride (TiN) (linear expansion coefficient=9.4×10⁻⁶/K) as a third sintering aid. The aluminum nitride powder (impurity oxygen content 0.8% by weight), the first sintering aid, the second sintering aid, and the third sintering aid used each had a mean particle diameter of 1 μm. The sintering temperature was 1720° C. The results are shown in Table 5.

TABLE 5

| | Comparative | | |
|---|---|---|---|
| | material | | |
| | (sample 2) | Sample 24 | Sample 25 |
| Mixing amount of Y₂O₃ | 4.7 | 4.2 | 3.8 |
| (pts. wt) | | | |
| Mixing amount of Al₂O₃ | 1.9 | 1.7 | 2.9 |
| (pts. wt) | | | |
| Mixing amount of TiN | 0 | 10.1 | 18.3 |
| (pts. wt) | | | |
| Volume fraction of AlN | 93.9 | 87.9 | 82.6 |
| phase in sintered compact | | | |
| Mean grain diameter | 7.0 | 5.6 | 3.7 |
| Constituent phase | Mainly YAP | Mainly TiN | Mainly TiN |
| | | and YAG | and YAG |
| Thermal conductivity | 165 | 66 | 51 |
| | Mean linear expansion coefficient | | |
| Temp. (° C.) | (×10⁻⁶/° C.) | | |
| 20-100 | 3.2 | 3.6 | 4.1 |
| 20-200 | 3.9 | 4.1 | 4.6 |
| 20-300 | 4.3 | 4.4 | 4.9 |
| 20-400 | 4.5 | 4.7 | 5.2 |
| 20-500 | 4.8 | 4.9 | 5.4 |
| 20-600 | 4.9 | 5.1 | 5.6 |
| 20-700 | 5.1 | 5.3 | 5.7 |
| 20-800 | 5.2 | 5.5 | 5.9 |
| 20-900 | 5.3 | 5.5 | 6.0 |
| 20-1000 | 5.5 | 5.7 | 6.1 |
| 20-1100 | 5.5 | 5.8 | 6.2 |
| 20-1200 | 5.6 | 5.8 | 6.2 |
| 20-1300 | 5.6 | 5.9 | 6.3 |

The results in Table 5 show that, even when TiN was used, the linear expansion coefficient could be regulated.

### Example 6

The polycrystalline aluminum nitride substrates prepared in samples 1 to 25 was fabricated into disks having a size of 2 inches (50.8 mm) in diameter×1 mm in thickness and a surface roughness Ra of 0.01 μm. Each of the samples was used for the growth of GaN semiconductor crystals.

The sample (polycrystalline aluminum nitride substrate) was placed on a susceptor within a MOCVD device. A GaN buffer layer was formed by a metal-organics chemical vapor deposition method (MOCVD method) at 500 to 600° C. while allowing a TMG gas (trimethyl gallium gas) and an ammonium gas to flow. The thickness of the GAN layer was increased (by crystal growth) at 1000° C. to 1100° C. The thickness of the buffer layer was 0.02 μm, and the final thickness of the GaN layer was 3 μm. The GaN layer was provided on the surface of the polycrystalline aluminum nitride substrate (diameter 2 inches).

The presence or absence of warpage was determined for the GaN-base semiconductors thus obtained. Samples free from the warpage defect (that are usable in the next step) were indicated by “◯”; and samples involving the warpage defect (that are unsable in the next step) were indicated by “×.” The results are shown in Table 6.

TABLE 6

| | Warpage |
|---|---|
| Sample 1 | X |
| Sample 2 | ◯ |
| Sample 3 | ◯ |
| Sample 4 | ◯ |
| Sample 5 | ◯ |
| Sample 6 | ◯ |
| Sample 7 | ◯ |
| Sample 8 | X |
| Sample 9 | X |
| Sample 10 | ◯ |
| Sample 11 | ◯ |
| Sample 12 | ◯ |
| Sample 13 | ◯ |
| Sample 14 | X |
| Sample 15 | X |
| Sample 16 | ◯ |
| Sample 17 | ◯ |
| Sample 18 | ◯ |
| Sample 19 | ◯ |
| Sample 20 | X |
| Sample 21 | ◯ |
| Sample 22 | ◯ |
| Sample 23 | ◯ |
| Sample 24 | ◯ |
| Sample 25 | ◯ |

The results show that, in order to obtain single crystals of GaN with little or no warpage, a mean linear expansion coefficient of 4.9×10⁻⁶/K to 6.1×10⁻⁶/K between 20° C. and 600° C. and a mean linear expansion coefficient of 5.5×10⁻⁶/K to 6.6×10⁻⁶/K between 20° C. and 1100° C. are important.

For the samples of Examples (samples 2 to 7, 10 to 13, 16 to 19, and 21 to 25), a high thermal conductivity of not less than 46 W/m/K contributes to good heat radiation, and this property is also considered as useful for the suppression of warpage defects. Accordingly, light emitting elements such as LEDs and semiconductor lasers can be efficiently manufactured.

### DESCRIPTION OF REFERENCE CHARACTERS

1 . . . polycrystalline aluminum nitride base material

2 . . . GaN-base semiconductor layer

3 . . . buffer layer

L . . . diameter of polycrystalline aluminum nitride base material

W . . . thickness of polycrystalline aluminum nitride base material

1. A polycrystalline aluminium nitride base material for use as a substrate material for crystal growth of GaN-base semiconductors, the polycrystalline aluminium nitride base material having a mean linear expansion coefficient of 4.9×10⁻⁶/K to 6.1×10⁻⁶/K between 20° C. and 600° C. and 5.5×10⁻⁶/K to 6.6×10⁻⁶/K between 20° C. and 1100° C.

2. The polycrystalline aluminum nitride base material according to claim 1, which comprises an aluminum nitride crystal and a grain boundary phase, the content of the aluminum nitride crystal being 56.2% to 93.9% in terms of volume fraction.

3. The polycrystalline aluminum nitride base material according to claim 1, wherein the grain boundary phase comprises a composite oxide composed of at least one material selected from the group consisting of Ca (calcium), Y (yttrium), La (lanthanum), Ce (cerium), Nd (neodymium), Pr (praseodymium), Eu (europium), Gd (gadolinium), Dy (dysprosium), Ho (holmium), Er (erbium), Yb (ytterbium), and Lu (lutetium) and aluminum.

4. The polycrystalline aluminum nitride base material according to claim 1, wherein the grain boundary phase contains titanium nitride (TiN).

5. The polycrystalline aluminum nitride base material according to claim 1, wherein crystal grains of the aluminum nitride have a mean diameter of not more than 7 μm.

6. The polycrystalline aluminum nitride base material according to claim 1, which has a thermal conductivity of not less than 46 W/m·K.

7. The polycrystalline aluminum nitride base material according to claim 1, which has a diameter of not less than 50 mm.

8. The polycrystalline aluminum nitride base material according to claim 1, which has a surface roughness (Ra) of not more than 0.2 μm and a thickness of not more than 3 mm.

9. A method for manufacturing a GaN-base semiconductor, the method comprising: growing a GaN-base semiconductor crystal using a polycrystalline aluminum nitride base material according to claim 1.

10. The method for manufacturing a GaN-base semiconductor according to claim 9, wherein the GaN-base semiconductor crystal is grown through a buffer layer.

11. The method for manufacturing a GaN-base semiconductor according to claim 9, wherein the GaN-base semiconductor is at least one semiconductor selected from the group consisting of GaN, InGaN, AlGaN, and InAlGaN.
